(19) United States
(12) Patent Application Publication
(10) Pub. No.: US 2014/0071783 A1
(43) Pub. Date: Mar. 13, 2014

(54) MEMORY DEVICE WITH CLOCK GENERATION BASED ON SEGMENTED ADDRESS CHANGE DETECTION

(71) Applicants: Rahul Sahu, Nagar (IN); Vikash, Bangalore (IN)

(72) Inventors: Rahul Sahu, Nagar (IN); Vikash, Bangalore (IN)

(73) Assignee: LSI Corporation, Milpitas, CA (US)

(21) Appl. No.: 13/613,981

(22) Filed: Sep. 13, 2012

(51) Int. Cl. G11C 8/00

(52) U.S. Cl. 365/230.08; 365/233.1

(57) ABSTRACT

A memory device comprises a memory array and associated control circuitry. The control circuitry comprises a clock generator configured to generate a clock signal for controlling timing of at least one of a read operation and a write operation directed to the memory array. The clock generator comprises a plurality of sets of address change detection circuits. The sets are configured to generate respective output signals as a function of respective subsets of address bits of an address signal identifying an address in the memory array. The clock generator further comprises logic circuitry coupled to the sets of address change detection circuits and configured to receive the respective output signals therefrom and to generate the clock signal as a function of said output signals.

### BACKGROUND

A semiconductor memory device typically includes an array of memory cells arranged in rows and columns, with each memory cell configured to store at least one data bit. The memory cells within a given row of the array are coupled to a common wordline, while the memory cells within a given column of the array are coupled to a common bitline. Thus, the array includes a memory cell at each point where a wordline intersects with a bitline.

In a semiconductor memory device of the type described above, data may be written to or read from the memory cells of the array using a memory cycle that is divided into an active phase and a precharge phase, with the active phase being used to read or write one or more memory cells of the array and the precharge phase being used to precharge the bitlines to a precharge voltage in preparation for the next cycle. Reading a given memory cell generally comprises transferring data stored within that cell to its corresponding bitline, and writing a given memory cell generally comprises transferring data into that cell from its corresponding bitline.

For a given read or write operation, the corresponding memory cycle is more particularly referred to as a read cycle or a write cycle, respectively. In certain types of memory devices, such as static random access memories (SRAMs), the read and write cycle times are not equal. The read access time is typically longer than the write access time, while the write precharge time is longer than the read precharge time.

As is well known to those skilled in the art, read and write self-time tracking arrangements may be used in order to establish appropriate signal timing for respective read and write operations. Such self-time tracking functionality is often designed to control the read and write signal timing over expected process, voltage and temperature (PVT) variations. This is particularly important for high-speed operations having read and write cycle frequencies in the gigahertz (GHz) range.

A conventional self-time tracking arrangement of this type utilizes a dummy row of memory cells and a dummy column of memory cells, associated with a dummy wordline and a dummy bitline, respectively, with those memory cells being configured in substantially the same manner as the actual memory cells of the memory array. A dummy wordline driver generates a dummy wordline signal for application to the dummy wordline with substantially the same timing as an actual wordline signal applied to an actual wordline of the memory array. The dummy wordline and dummy bitline are also known as a self-time wordline (STWL) and a self-time bitline (STBL), respectively.

In order to permit independent control of the read and write cycle times, self-time tracking circuitry may be separated into two paths, one for read and another for write. This approach is also called dual mode self-time (DMST).

Conventional approaches to reading data from a memory cell include the use of differential sense amplifiers. In a typical conventional arrangement, sense amplifiers are associated with respective columns of the memory array. For each read memory cycle, the sense amplifier is turned on in order to sense data on a corresponding bitline, and then turned off once the sensed data is latched at the sense amplifier output. The sense amplifier is turned on and off responsive to respective logic states of a sense amplifier enable signal. The turning on and turning off of the sense amplifier is also referred to as enabling and disabling the sense amplifier. The use of differential sense amplifiers generally provides faster sensing with lower dynamic power consumption than single-ended sensing arrangements.

However, controlling the timing of the transitions in the sense amplifier enable signal can be problematic, particularly for high-speed read operations. For example, in conventional arrangements, the sense amplifier enable signal may be provided by a sense latch, with the sense latch being set and reset in order to turn on and turn off the sense amplifiers. More particularly, the sense latch may be reset responsive to a pulse of a sense off signal that corresponds to a delayed and inverted version of the sense amplifier enable signal, as returned to the sense latch from a final one of the sense amplifiers. It can be very difficult to accurately control the delay of the sense off signal, particularly over PVT variations. As a result, read memory cycle time is increased, thereby degrading memory access time performance.

These and other memory device read and write timing issues are addressed in one or more of U.S. patent application Ser. No. 13/433,637, filed Mar. 29, 2012 in the name of S. Sharad et al. and entitled “Memory Device having Control Circuitry for Sense Amplifier Reaction Time Tracking,” U.S. patent application Ser. No. 13/561,673, filed Jul. 30, 2012 in the name of M. Trivedi et al. and entitled “Memory Device with Separately Controlled Sense Amplifiers,” and U.S. patent application Ser. No. 13/482,197, filed May 29, 2012 in the name of Vikash et al. and entitled “Memory Device having Control Circuitry for Write Tracking using Feedback-Based Controller,” all of which are commonly assigned herewith and incorporated by reference herein.

Memory devices of the type described above may incorporate one or more asynchronous read ports. In an asynchronous read port, any time there is a change in one or more bits of an address signal, such as would occur in the case of a new address being processed by the device, a read operation is performed on the addressed memory location.

### SUMMARY

We have determined that, in a memory with an asynchronous read port, as the address length increases as a function of the number of rows in the memory array, it can become increasingly difficult to generate an accurate internal clock for controlling the timing of read operations. This is due at least in part to a large variable delay spread in the generation of such a clock signal, between a maximum delay case which occurs when there is a transition in only a single bit of the address and a minimum delay case which occurs when there are transitions in all of the bits of the address. This problem becomes worse over the above-noted PVT variations, again leading to increased read memory cycle time, such that memory access time performance is degraded.

Illustrative embodiments of the invention provide a memory device in which an internal clock signal is generated from address signals using a technique referred to herein as segmented address change detection, which substantially reduces the variable delay spread between maximum and minimum delay cases. This allows more accurate timing control over PVT variations, thereby facilitating high-speed operations.

In one embodiment, a memory device comprises a memory array and associated control circuitry. The control circuitry comprises a clock generator configured to generate a clock signal for controlling timing of at least one of a read operation and a write operation directed to the memory array. The clock generator comprises a plurality of sets of address change detection circuits. The sets are configured to generate respective output signals as a function of respective subsets of address bits of an address signal identifying an address in the memory array. The clock generator further comprises logic circuitry coupled to the sets of address change detection circuits and configured to receive the respective output signals therefrom and to generate the clock signal as a function of said output signals.

By way of example, each of the address change detection circuits in a given one of the sets may comprise a first output signal line providing an address change detection output signal specific to that address change detection circuit, and a second output signal line adapted for coupling to a common output signal line associated with all of the address change detection circuits of the given set.

One or more of the illustrative embodiments can provide a memory device that exhibits shorter read memory cycles, as well as improved overall operating performance, relative to conventional devices. More particularly, the use of segmented address change detection as disclosed herein can provide an internal clock signal with significantly reduced delay spread, even for memory devices that use addresses having large numbers of address bits, while also reducing susceptibility to PVT variations.

A memory device in accordance with embodiments of the invention may be implemented, for example, as a stand-alone memory device, such as a packaged integrated circuit, or as an embedded memory in a microprocessor or other processing device.

### BRIEF DESCRIPTION OF THE DRAWINGS

FIG. 1 is a block diagram of a semiconductor memory device comprising a memory array and incorporating associated control circuitry that generates a clock signal using segmented address change detection functionality in an illustrative embodiment of the invention.

FIG. 2 shows an example of an address change detection circuit in an illustrative embodiment.

FIG. 3 shows a set of address change detection circuits and an associated latch circuit and output inverter in an illustrative embodiment.

FIG. 4 shows one possible embodiment of a clock generator implemented in the control circuitry of the memory device of FIG. 1 using multiple sets of address change detection circuits configured to provide segmented address change detection functionality.

FIG. 5 is a block diagram of a processing device which incorporates the memory device of FIG. 1.

FIG. 6 is a block diagram of a processor integrated circuit which incorporates the memory device of FIG. 1 as an embedded memory.

### DETAILED DESCRIPTION

Embodiments of the invention will be illustrated herein in conjunction with exemplary semiconductor memory devices that incorporate control circuitry with segmented address change detection functionality. It should be understood, however, that embodiments of the invention are more generally applicable to any semiconductor memory device in which improvements in at least one of read and write performance are desired, and may be implemented using circuitry other than that specifically shown and described in conjunction with the illustrative embodiments.

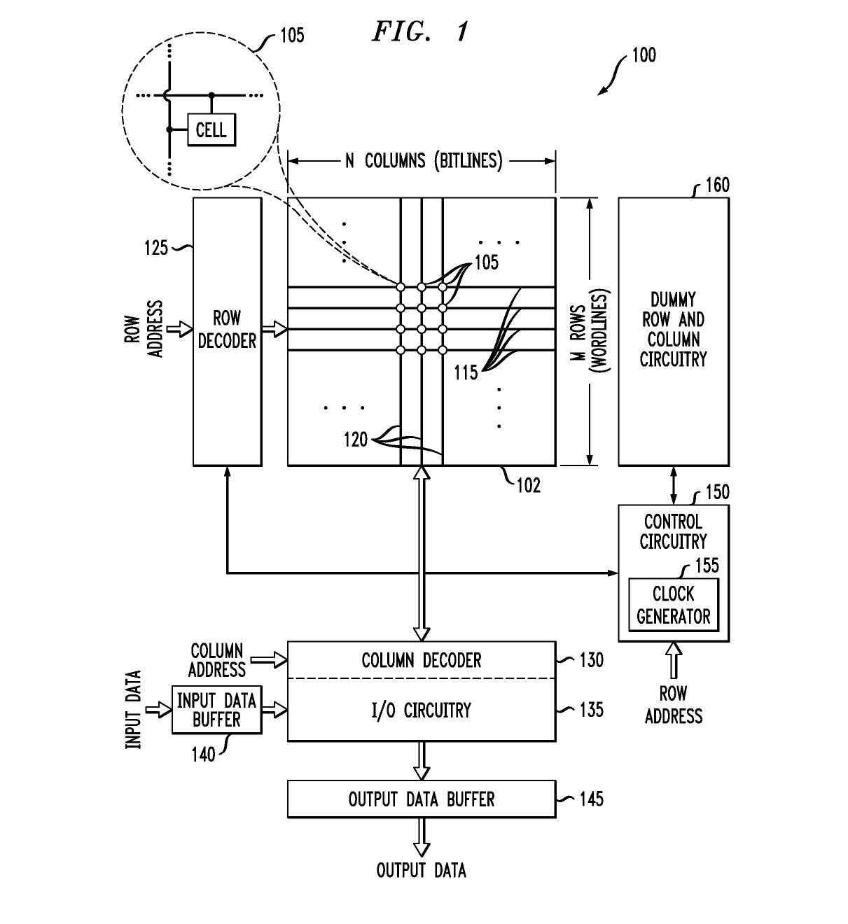

FIG. 1 shows a block diagram of a memory device 100 in accordance with an illustrative embodiment of the invention. The memory device 100 comprises a memory array 102. The memory array 102 comprises a plurality of memory cells 105 each configured to store a single bit of data. Such memory cells are also referred to herein as “bitcells.” Each cell 105 is coupled to a corresponding row or wordline 115 and column or bitline 120. The memory array therefore includes a memory cell at each point where a wordline intersects with a bitline. The memory cells of the memory array are illustratively arranged in N columns and M rows. The values selected for N and M in a given implementation will generally depend upon on the data storage requirements of the application in which the memory device is utilized. In some embodiments, one of N and M may have value 1, resulting in an array comprising a single column or a single row of memory cells.

Particular ones of the memory cells 105 of the memory array 102 can be activated for writing data thereto or reading data therefrom by application of appropriate row and column addresses to respective row decoder 125 and column decoder 130. Other elements of the memory device 100 include input/output (I/O) circuitry 135, an input data buffer 140 and an output data buffer 145. The I/O circuitry 135 in the present embodiment is assumed by way of example to comprise a plurality of sense amplifiers, such as differential sense amplifiers coupled to respective columns of the memory array 102. The operation of these and other memory device elements, such as row decoder 125, column decoder 130, and buffers 140 and 145, is well understood in the art and will not be described in detail herein.

Although memory array 102 is identified in FIG. 1 as comprising the cells 105 and their associated wordlines and bitlines 115 and 120, the term “memory array” as used herein is intended to be more broadly construed, and may encompass one or more associated elements such as the row and column decoders 125 and 130, the I/O circuitry 135, or the input and output data buffers 140 and 145, or portions thereof.

Also, the wordlines 115 and bitlines 120, although shown as respective single lines in FIG. 1, may each comprise a corresponding pair of differential lines. By way of example, differential bitlines BL and BLB may be used. Also, separate read and write wordlines or bitlines may be used, and a given such read or write wordline or bitline may comprise a corresponding pair of differential lines.

The memory device 100 in one or more of the illustrative embodiments may be assumed to comprise a static random access memory (SRAM) device. However, as indicated previously, the disclosed control circuitry with segmented address change detection functionality can be adapted in a straightforward manner for use with other types of memory devices, including, for example, dynamic random access memory (DRAM), electrically erasable programmable ROM (EEPROM), magnetic RAM (MRAM), ferroelectric RAM (FRAM), phase-change RAM (PC-RAM), etc. Also, other types of memory cell configurations may be used. For example, the memory cells 105 in the memory array 102 could be multi-level cells each configured to store more than one bit of data. Embodiments of the invention are therefore not limited in terms of the particular storage or access mechanism utilized in the memory device.

The present embodiment of memory device 100 includes control circuitry 150 that is configured to generate a clock signal from an address signal in a clock generator 155. The control circuitry 150 more particularly generates the clock signal in clock generator 155 using a technique referred to herein as segmented address change detection, which substantially reduces the variable delay spread between maximum and minimum delay cases. As mentioned previously, in generating a clock signal based on address change detection without address segmentation, the maximum delay case occurs when there is a transition in only a single bit of the address and the minimum delay case which occurs when there are transitions in all of the bits of the address. The use of the segmented address change detection technique in the present embodiment allows more accurate timing control over PVT variations, thereby facilitating high-speed operations.

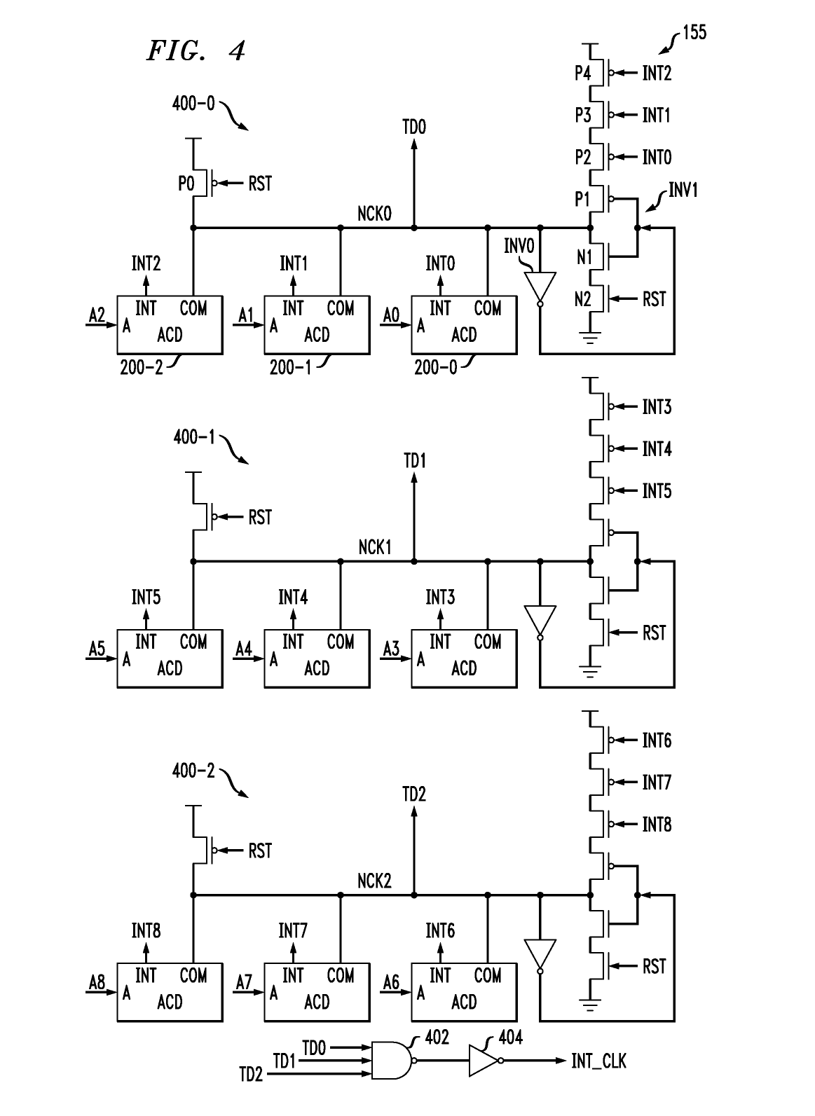

It is further assumed that the memory device 100 comprises at least one asynchronous read port, and that the clock signal is an internal clock signal for the memory device and is generated by the clock generator 155 based on an address signal illustratively comprising a row address. The clock generator 155 is therefore configured to generate a clock signal for controlling timing of at least one of a read operation and a write operation directed to the memory array 102. Associated with the memory array 102 and control circuitry 150 in the present embodiment is dummy row and column circuitry 160. Such dummy row and column circuitry may be configured to implement self-timing arrangements for use in generating reset signals of the type referred to in conjunction with FIGS. 3 and 4 below.

The memory device 100 as illustrated in FIG. 1 may include other elements in addition to or in place of those specifically shown, including one or more elements of a type commonly found in a conventional implementation of such a memory device. These and other conventional elements, being well understood by those skilled in the art, are not described in detail herein. It should also be understood that the particular arrangement of elements shown in FIG. 1 is presented by way of illustrative example only. Those skilled in the art will recognize that a wide variety of other memory device configurations may be used in implementing embodiments of the invention.

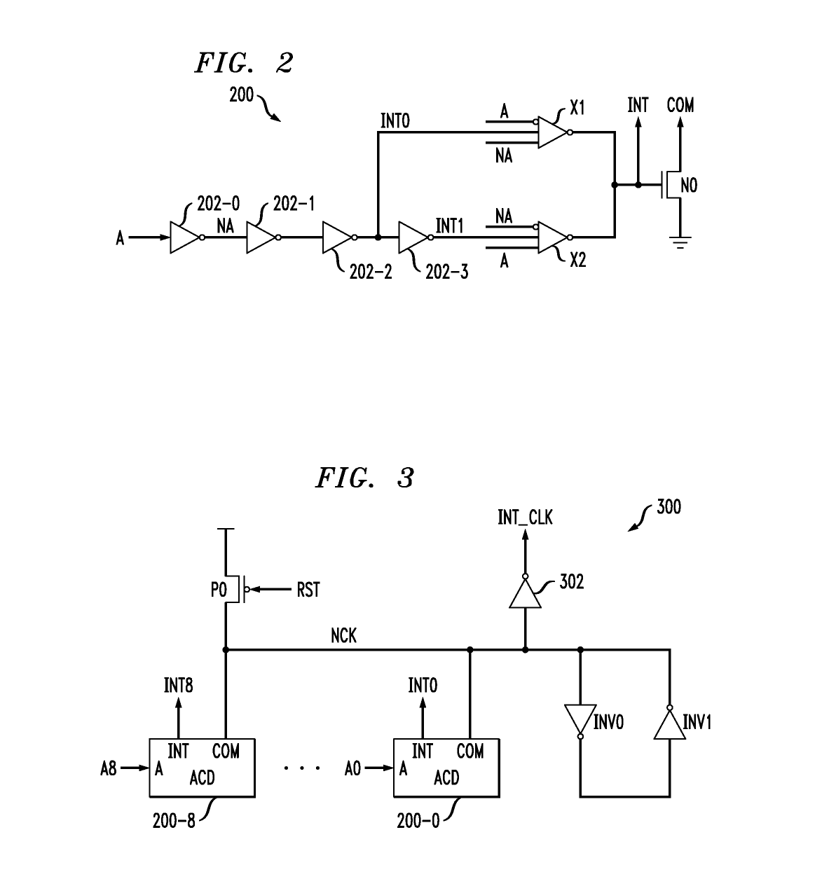

An illustrative embodiment of the clock generator 155 comprising a plurality of sets of address change detection circuits and associated logic circuitry for generating an internal clock signal based on detection of changes in an address signal will be described below in conjunction with FIG. 4. However, before describing the clock generator 155 in detail, an individual address change detection circuit will be described in conjunction with FIG. 2, and a set of address change detection circuits will be described in conjunction with FIG. 3.

Referring now to FIG. 2, a single address change detection circuit 200 of the clock generator 155 is shown. It is assumed that the address change detection circuit 200 is one of a plurality of such circuits that form a given one of a plurality of sets of address change detection circuits in implementing a segmented address change detection technique as disclosed herein. As indicated previously, examples of such sets are illustrated in FIG. 4.

In this embodiment, the address change detection circuit 200 comprises an inverter chain 202 comprising a series arrangement of a plurality of inverters denoted 202-0, 202-1, 202-2 and 202-3. Although four inverters are used in the inverter chain 202 in this embodiment, other embodiments may use different numbers of inverters. The initial inverter 202-0 of the inverter chain 202 receives as its input a given one of the address bits A of an address signal. The address change detection circuit 200 further comprises first and second tri-state inverters X1 and X2, and an output gate illustratively implemented as a single N-type metal-oxide-semiconductor (NMOS) transistor N0. Inputs of the first and second tristate inverters X1 and X2 are coupled to outputs of respective inverters 202-2 and 202-3 of the inverter chain 202. Other inputs of X1 and X2 are coupled to the address signal bit A and its complement NA as indicated in the figure. Outputs of the first and second tristate inverters X1 and X2 are coupled together and provide an address change detection circuit output signal INT specific to the given address change detection circuit 200.

The output gate N0 has an input coupled to the outputs of the first and second tristate inverters X1 and X2 and is configured to operate in conjunction with corresponding output gates from respective other address change detection circuits of a given set of such circuits to generate an output signal for that set.

As indicated above, the address change detection circuit 200 is one of a plurality of address change detection circuits in a given set of such circuits. Each such address change detection circuit, like address change detection circuit 200 of FIG. 1, has a first output signal line

INT at a gate terminal of N0 providing an address change detection output signal specific to that address change detection circuit and a second output signal line COM at a drain of N0 adapted for coupling to a corresponding common output signal line associated with all of the address change detection circuits of the given set.

In operation, the address change detection circuit 200 is configured to detect transitions in the input address bit A. More particularly, whenever there is any transition in logic level in address bit A, either from low to high or from high to low, N0 is turned on for an amount of time given by at least three inverter delays.

For example, assume that A=0, such that INT0=1 and INT1=0. In this case, tristate inverter X1 will be on and tristate inverter X2 will be off. When A transitions from low to high, its complement NA goes low after one inverter delay, which will turn on X2 such that N0 is turned on until INT1 goes high. A similar result occurs for a transition in address bit A from high to low.

FIG. 3 illustrates the manner in which a plurality of address change detection circuits 200-0 through 200-8 can be combined to form a set 300 of such address change detection circuits. Each of the address change detection circuits 200 is assumed to be configured in the manner shown in FIG. 2, and is denoted ACD as indicated. Associated with the set of 300 of address change detection circuits 200 is additional circuitry including a latch circuit comprising inverters INV0 and INV1, an output inverter 302, and a reset gate implemented as a P-type MOS device P0.

In this embodiment, an input address signal is assumed to comprise nine address bits denoted A0 through A8, each of which is applied to an address bit input of a corresponding one of the address change detection circuits 200-0 through 200-8. This embodiment does not use segmented address change detection, as all nine of the address bits are processed using a single set of address change detection circuits 200-0 through 200-8. These address change detection circuits 200-0 through 200-8 generate respective circuit-specific outputs INT0 through INT8, and each also has its common output COM coupled to a common output signal line denoted NCK that drives the input of inverter 302. The input of inverter INV0 is also coupled to the NCK signal line, as is the output of inverter INV1. Also, the output of inverter INV0 drives the input of inverter INV1. The inverters INV0 and INV1 are therefore connected in a back-to-back arrangement to form a latch circuit. Each of inverters INV0 and INV1 comprises an NMOS device and a PMOS device.

The FIG. 3 embodiment can be used to generate an internal clock INT_CLK at the output of inverter 302. In operation, the set 300 considers all of the address bits A0 through A8 together, and whenever there is any transition in logic level in any one of these address bits, either from low to high or from high to low, NCK is pulled down to a logic low level and the latch circuit comprising inverters INV0 and INV1 will latch the state of NCK, thereby generating a transition in the INT CLK signal. This internal clock signal is reset using reset signal RST applied to the gate terminal of P0. The reset signal RST can be generated using reaction time tracking techniques such as those disclosed in the above-cited U.S. patent application Ser. Nos. 13/433,637 and 13/561,673, which may make use of dummy row and column circuitry 160 associated with memory array 102.

An arrangement of the type illustrated in FIG. 3 can be problematic as the number of rows in the memory array 102 increases, such that a large number of address bits is required to address those rows. In the present embodiment, the COM outputs of all nine of the address change detection circuits 200-0 through 200-8 are coupled to the common signal line NCK, which adds substantial capacitance on that signal line, delaying the generation of the internal clock INT_{—} CLK. A maximum delay case occurs when there is a transition in only a single address bit, such as address bit A0, such that the output gate N0 of its corresponding address change detection circuit 200-0 has to discharge the large capacitance of node NCK while also fighting the PMOS device of INV1. A minimum delay case occurs when there are transitions in each of the nine address bits A0 through A8, such that the respective output gates N0 of their address change detection circuits N0 through N8 are all on and collectively operate in parallel to more quickly drive node NCK to the logic low level against the PMOS device of INV1. These two extreme cases lead to a significant delay spread, which can become worse over PVT variations, directly translating to a substantial access time penalty in reading data from the memory array 102.

These issues are addressed in the illustrative embodiment of FIG. 4, which shows an implementation of clock generator 155 using a segmented address change detection approach. In this embodiment, the clock generator 155 comprises a plurality of sets 400-0, 400-1 and 400-2 of address change detection circuits 200, with the sets configured to generate respective output signals TD0, TD1 and TD2 as a function of respective subsets of address bits of an address signal identifying an address in the memory array 102.

The clock generator 155 further comprises logic circuitry coupled to the sets 400 of address change detection circuits and configured to receive the respective output signals therefrom and to generate the clock signal INT_CLK as a function of the output signals TD0, TD1 and TD2. The logic circuitry in this embodiment more particularly comprises a first logic gate 402, illustratively a NAND gate, configured to receive the output signals TD0, TD1 and TD2 from the respective sets 400 of address change detection circuits 200, and an inverter 404 having an input coupled to an output of the first logic gate 402 and an output providing the clock signal INT_CLK.

The logic gates 402 and 404 therefore collectively provide one possible example of what is more generally referred to herein as “logic circuitry.” Although illustratively shown as a

NAND gate and inverter in the figure, different types and arrangements of logic circuitry can be used in other embodiments of the invention in implementing the disclosed functionality for generation of a clock signal using output signals from respective sets of address change detection circuits.

In the FIG. 4 embodiment, the nine address bits A0 through A8 are divided into three distinct subsets A0-A2, A3-A5 and A6-A8. Each of the sets 400-0, 400-1 and 400-2 of address change detection circuits comprises three address change detection circuits 200. The address change detection circuits 200 in a given one of the sets 400 of address change detection circuits are configured to receive as inputs respective address bits of the corresponding subset of address bits. Thus, set 400-0 includes address change detection circuits 200-0, 200-1 and 200-2 that receive as inputs the respective address bits A0, A1 and A2 of the corresponding subset, set 400-1 includes address change detection circuits 200-3, 200-4 and 200-5 that receive as inputs the respective address bits A3, A4 and A5 of the corresponding subset, and set 400-2 includes address change detection circuits 200-6, 200-7 and 200-8 that receive as inputs the respective address bits A6, A7 and A8 of the corresponding subset.

Each of the address change detection circuits 200 is assumed to be configured as previously described in conjunction with FIG. 2, although other types of address change detection circuits may be used in other embodiments.

Also, in this embodiment, each of the sets 400 of address change detection circuits 200 comprises three address change detection circuits, although other segmentations of address change detection circuits into sets may be used. For example, if the number of address bits is not evenly divisible by three, all but one of the sets of address detection circuits may each comprise three address change detection circuits and the remaining one of the sets of address detection circuit may comprise x=n mod 3 address detection circuits, where the address bits comprise a total of n address bits. Alternatively, one or more of the sets may each include more than three or fewer than three address change detection circuits. More generally, all but one of the sets of address detection circuits may each comprise m address change detection circuits and the remaining one of the sets of address detection circuits may comprise x=n mod m address detection circuits.

Each of the address change detection circuits 200 in a given one of the sets 400 comprises a first output signal line INT providing an address change detection output signal specific to that address change detection circuit, and a second output signal line COM adapted for coupling to a common output signal line associated with all of the address change detection circuits of the given set.

Accordingly, the address change detection circuits 200-0, 200-1 and 200-2 of set 400-0 generate respective circuit-specific outputs INT0, INT1 and INT2, and respective common outputs COM coupled to common output signal line NCK0 providing set output signal TD0. Similarly, the address change detection circuits 200-3, 200-4 and 200-5 of set 400-1 generate respective circuit-specific outputs INT3, INT4 and INT5, and respective common outputs COM coupled to common output signal line NCK1 providing set output signal TD1, and the address change detection circuits 200-6, 200-7 and 200-8 of set 400-2 generate respective circuit-specific outputs INT6, INT7 and INT8, and respective common outputs COM coupled to common output signal line NCK2 providing set output signal TD2.

Each of the sets 400 of address change detection circuits 200 further comprises a latch circuit that includes inverters INV0 and INV1, with the latch circuit being coupled to the common output signal line NCK0, NCK1 or NCK2 associated with all of the address change detection circuits 200 of the given set. In each of these latch circuits, the input of inverter INV0 and the output of inverter INV1 are coupled to the common signal line NCK0, NCK1 or NCK2. The inverters INV0 and INV1 are more particularly configured in a back-to-back arrangement, with an input of INV0 coupled to an output of INV1 and an input of INV1 coupled to an output of INV0, in a manner similar to that previously described in conjunction with FIG. 3. The inverter INV1 in each of the sets 400 comprises an NMOS device N1 and a PMOS device P1.

The reset signal RST for each of the sets 400 of address change detection signals 200 is applied to a gate terminal of a corresponding additional NMOS transistor N2 which has its drain terminal coupled to a source terminal of N1 and its source terminal coupled to a lower supply voltage, illustratively ground potential. The reset signal RST is also applied to a gate terminal of the PMOS transistor P0 associated with each set 400, in a manner similar to that previously described in conjunction with FIG. 3.

The latch circuit associated with a given one of the sets 400 of address change detection circuits 200 is operative only if each of a plurality of address change detection circuit output signals INT specific to the respective address change detection circuits of the given set has a predetermined logic level. This is accomplished in the present embodiment by providing a plurality of additional PMOS transistors P2, P3 and P4 arranged in series between a voltage supply input of the latch circuit at the source of P1 and a corresponding voltage supply, with the transistors receiving at their respective gate terminals respective address change detection circuit output signals INT specific to the respective address change detection circuits of the given set, such that the latch circuit is decoupled from the voltage supply if any two of the address change detection circuit output signals have different logic levels.

Thus, in the present embodiment, the latch circuit associated with set 400-0 is operative only if the circuit-specific output signals INT0, INT1 and INT2 applied to the respective gate terminals of P2, P3 and P4 are all at the logic low level, such that P2, P3 and P4 are all turned on, connecting the source of P1 to the upper supply voltage. The corresponding PMOS transistors in the upper supply voltage path of the latch circuits in the other sets 400-1 and 400-2 are configured to operate in a similar manner, using their respective sets of circuit-specific output signals INT3-INT5 and INT6-INT8.

In the FIG. 4 arrangement, which involves nine address bit A0 through A8, the capacitance of the address change detection circuits 200 is distributed across the three distinct signal lines NCK0, NCK1 and NCK2, one in each of the sets 400, rather than applied to the single common output signal line NCK as in the FIG. 3 embodiment. The two extreme cases defining the delay spread in FIG. 4 are the maximum delay case which occurs when there is a transition in one address bit in any of the three sets, and the minimum delay case which occurs when there are transitions on all of the address bits in any of the three sets. Accordingly, the delay spread is significantly reduced. For example, a delay spread of about 70 picoseconds (ps) in the FIG. 3 embodiment can be reduced to a delay spread of about 20 ps by using the segmented address change detection approach of FIG. 4, leading to a substantial improvement in access time.

As indicated previously, segmentation of the address change detection circuits 200 into sets of three is described by way of illustrative example only, and numerous other types of segmentation can be used in other embodiments. In an embodiment in which the total number of address bits and associated address change detection circuits is not evenly divisible by three or other desired basic set number, any remaining address change detection circuits less than that number can be placed in a separate set and its common output applied to an additional input of the logic circuitry that generates the INT_CLK signal.

The illustrative embodiment described in conjunction with FIG. 4 provides fast generation of an internal clock signal with significantly reduced delay spread, even for memory devices that use addresses having large numbers of address bits. Moreover, susceptibility of the delay spread to PVT variations is considerably reduced. This reduces read cycle time and improves the overall operating performance of the memory device 100.

It is to be appreciated that the particular control circuitry configurations illustrated in FIGS. 2 and 4 are presented by way of illustrative example only, and other embodiments may use other types and arrangements of control circuitry. The term “control circuitry” as used herein is therefore intended to be broadly construed, and should not be viewed as being limited to the particular arrangements shown and described in conjunction with the illustrative embodiments.

For example, in one or more of these other embodiments, the conductivity types of at least a subset of the PMOS and NMOS transistors of the control circuitry may be reversed, and other suitable modifications may be made to the circuitry and associated signaling levels, as would be appreciated by one skilled in the art. Also, other types of address change detection circuits, logic circuitry and other memory device components may be used in implementing other embodiments. The term “address change detection circuit” as used herein is therefore intended to be broadly construed so as to encompass a wide variety of different arrangements of detection circuitry. Also, a given set of such circuits may be viewed as encompassing associated circuitry such as latch circuits, reset transistors such as P0 and N2, and supply voltage control transistors such as P2, P3 and P4.

Embodiments of the invention are particularly well suited for use in high-speed SRAMs and DRAMs with asynchronous read ports, as well as other types of memories that demand high read speeds, such as content-addressable memories (CAMs) and processor register files.

A given memory device configured in accordance with an embodiment of the invention may be implemented as a stand-alone memory device, for example, as a packaged integrated circuit memory device suitable for incorporation into a higher-level circuit board or other system. Other types of implementations are possible, such as an embedded memory device, where the memory may be, for example, embedded into a processor or other type of integrated circuit device which comprises additional circuitry coupled to the memory device. More particularly, a memory device as described herein may comprise, for example, an embedded memory implemented within a microprocessor, digital signal processor (DSP), application-specific integrated circuit (ASIC), field-programmable gate array (FPGA) or other type of processor or integrated circuit device.

FIG. 5 shows an embodiment of a processing device 500 which incorporates the memory device 100 of FIG. 1. In this embodiment, the memory device 100 is coupled to a processor 502. The processing device further includes interface circuitry 504 coupled to the processor 502. The processing device 500 may comprise, for example, a computer, a server or a portable communication device such as a mobile telephone. The interface circuitry 504 may comprise one or more transceivers for allowing the device 500 to communicate over a network.

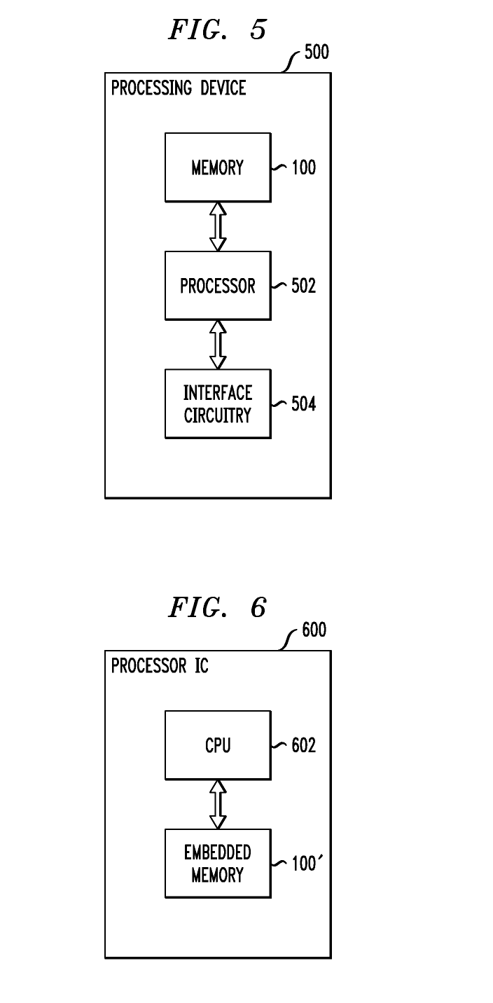

Alternatively, processing device 500 may comprise a microprocessor, DSP or ASIC, with processor 502 corresponding to a central processing unit (CPU) and memory device 100 providing at least a portion of an embedded memory of the microprocessor, DSP or ASIC. FIG. 6 shows an example of an arrangement of this type, with processor integrated circuit 600 incorporating the memory device of FIG. 1 as an embedded memory 100′. The embedded memory 100′ in this embodiment is coupled to a CPU 602. The embedded memory may comprise, for example, a high-speed register file. Numerous alternative embedded memory embodiments are possible.

As indicated above, embodiments of the invention may be implemented in the form of integrated circuits. In fabricating such integrated circuits, identical die are typically formed in a repeated pattern on a surface of a semiconductor wafer. Each die includes a memory device with a memory array and control circuitry implementing segmented address change detection functionality as described herein, and may include other structures or circuits. The individual die are cut or diced from the wafer, then packaged as an integrated circuit. One skilled in the art would know how to dice wafers and package die to produce integrated circuits. Integrated circuits so manufactured are considered embodiments of this invention.

Again, it should be emphasized that the above-described embodiments of the invention are intended to be illustrative only. For example, other embodiments can use different types and arrangements of memory arrays, memory cell circuitry, control circuitry, address change detection circuits, address change detection circuit set arrangements, logic circuitry, transistor conductivity types, control signals, and other elements for implementing the described functionality. These and numerous other alternative embodiments within the scope of the following claims will be apparent to those skilled in the art.

What is claimed is:

1. A memory device comprising:
a memory array; and
control circuitry comprising a clock generator configured to generate a clock signal for controlling timing of at least one of a read operation and a write operation directed to the memory array;
wherein the clock generator comprises:
a plurality of sets of address change detection circuits, the sets configured to generate respective output signals as a function of respective subsets of address bits of an address signal identifying an address in the memory array; and
logic circuitry coupled to the sets of address change detection circuits and configured to receive the respective output signals therefrom and to generate the clock signal as a function of said output signals.

2. The memory device of claim 1 wherein the address change detection circuits in a given one of the sets of address change detection circuits are configured to receive as inputs respective address bits of the corresponding subset of address bits.

3. The memory device of claim 1 wherein two or more of the sets of address change detection circuits each comprise at least three address change detection circuits.

4. The memory device of claim 1 wherein all but one of the sets of address detection circuits each comprise m address change detection circuits and the remaining one of the sets of address detection circuits comprises x=n mod m address detection circuits, where the address bits comprise a total of n address bits.

5. The memory device of claim 1 wherein each of the address change detection circuits in a given one of the sets comprises a first output signal line providing an address change detection output signal specific to that address change detection circuit and a second output signal line adapted for coupling to a common output signal line associated with all of the address change detection circuits of the given set.

6. The memory device of claim 1 wherein a given one of the address change detection circuits in a given one of the sets of address change detection circuits comprises:
an inverter chain comprising a series arrangement of a plurality of inverters;
first and second tri-state inverters; and
an output gate;
wherein an initial inverter of the inverter chain receives as its input a given one of the address bits;
wherein inputs of the first and second tristate inverters are coupled to outputs of respective subsequent inverters of the inverter chain, and outputs of the first and second tristate inverters are coupled together and provide an address change detection circuit output signal specific to the given address change detection circuit; and
wherein the output gate has an input coupled to the outputs of the first and second tristate inverters and is configured to operate in conjunction with corresponding output gates from respective other address change detection circuits of the given set to generate the output signal for that set.

7. The memory device of claim 6 wherein the inputs of the respective first and second tristate inverters are coupled to respective outputs of second-to-last and last inverters of the inverter chain.

8. The memory device of claim 1 wherein a given one of the sets of address change detection circuits further comprises a latch circuit coupled to a common output signal line associated with all of the address change detection circuits of the given set.

9. The memory device of claim 8 wherein the latch circuit comprises first and second inverters with an input of the first inverter coupled to an output of the second inverter and an input of the second inverter coupled to an output of the first inverter.

10. The memory device of claim 8 wherein the latch circuit is operative only if each of a plurality of address change detection circuit output signals specific to the respective address change detection circuits of the given set has a predetermined logic level.

11. The memory device of claim 8 wherein the given set of address change detection circuits further comprises a plurality of transistors arranged in series between a voltage supply input of the latch circuit and a corresponding voltage supply, with the transistors receiving as their respective control inputs respective address change detection circuit output signals specific to the respective address change detection circuits of the given set, such that the latch circuit is decoupled from the voltage supply if any two of the address change detection circuit output signals have different logic levels.

12. The memory device of claim 1 wherein the logic circuitry comprises:
a first logic gate configured to receive the output signals from the respective sets of address change detection circuits; and
an inverter having an input coupled to an output of the first logic gate and an output providing the clock signal.

13. An integrated circuit comprising the memory device of claim 1.

14. A processing device comprising the memory device of claim 1.

15. A method comprising:
providing a plurality of sets of address change detection circuits;
generating in the sets of address change detection circuits respective output signals as a function of respective subsets of address bits of an address signal identifying an address in a memory array; and
generating a clock signal for controlling timing of at least one of a read operation and a write operation directed to the memory array as a function of said output signals.

16. The method of claim 15 wherein generating a given one of the output signals comprises latching an output signal line providing the output signal of the given set wherein the output signal line is coupled to common outputs of each of the address change detection circuits of the given set.

17. The method of claim 16 wherein latching the output signal line comprises latching the output signal line only if each of a plurality of address change detection circuit output signals specific to the respective address change detection circuits of the given set has a predetermined logic level.

18. An apparatus comprising:
control circuitry adapted for coupling to a memory array;
the control circuitry comprising a clock generator configured to generate a clock signal for controlling timing of at least one of a read operation and a write operation directed to the memory array;
wherein the clock generator comprises:
a plurality of sets of address change detection circuits, the sets configured to generate respective output signals as a function of respective subsets of address bits of an address signal identifying an address in the memory array; and
logic circuitry coupled to the sets of address change detection circuits and configured to receive the respective output signals therefrom and to generate the clock signal as a function of said output signals.

19. The apparatus of claim 18 wherein each of the address change detection circuits in a given one of the sets comprises a first output signal line providing an address change detection output signal specific to that address change detection circuit and a second output signal line adapted for coupling to a common output signal line associated with all of the address change detection circuits of the given set.

20. The apparatus of claim 18 wherein a given one of the sets of address change detection circuits further comprises a latch circuit coupled to a common output signal line associated with all of the address change detection circuits of the given set.
